(19) United States
(12) Patent Application Publication
(10) Pub. No.: US 2021/0178515 A1
(43) Pub. Date: Jun. 17, 2021

(54) BONDING ARRANGEMENT AND BONDING TOOL

(71) Applicant: Hesse GmbH, Paderborn (DE)

(72) Inventors: Andreas UNGER, Verl (DE); Michael BROEKELMANN, Delbrueck (DE); Matthias HUNSTIG, Paderborn (DE)

(73) Assignee: Hesse GmbH, Paderborn (DE)

(21) Appl. No.: 17/188,798

(22) Filed: Mar. 1, 2021

Related U.S. Application Data
(63) Continuation of application No. PCT/DE2019/100694, filed on Jul. 29, 2019.

(30) Foreign Application Priority Data
Aug. 27, 2018 (DE) 10 2018 120 822.7

(51) Int. Cl. B23K 26/06

(52) U.S. Cl. CPC B23K 26/0643; B23K 26/21

(57) ABSTRACT

The invention relates to a bonding arrangement comprising a bonding tool including a tool shank, which is designed as elongated in a tool longitudinal direction, and including a tool tip, which adjoins the tool shank, and comprising a light guide designed to conduct a laser beam, the light guide being provided in a longitudinal recess of the bonding tool, the longitudinal recess extending from an end face of the bonding tool opposite the tool tip in the direction of the tool tip, a functional recess being formed on the lateral surface of the bonding tool, and the longitudinal recess being made to extend up to the functional recess. The invention further relates to a bonding tool having a functional application as well as the use of the bonding arrangement according to the invention and/or the bonding tool for ultrasonic bonding.

This nonprovisional application is a continuation of International Application No. PCT/DE2019/100694, which was filed on Jul. 29, 2019 and which claims priority to German Patent Application No. 10 2018 120 822.7, which was filed in Germany on Aug. 27, 2018 and which are both herein incorporated by reference.

### BACKGROUND OF THE INVENTION

### Field of the Invention

The present invention relates to a bonding arrangement comprising a bonding tool including a tool shank, which is designed as elongated in a longitudinal direction of the tool, and including a tool tip, which adjoins the tool shank, and comprising a light guide designed to conduct a laser beam, the light guide being provided in a longitudinal recess of the bonding tool, and the longitudinal recess extending from an end face of the bonding tool opposite the tool tip in the direction of the tool tip.

The invention further relates to a bonding tool, including an tool shank, elongated in a longitudinal direction of the tool, and including a tool tip, which adjoins the tool shank, and including a longitudinal recess, which extends from an end face of the bonding tool opposite the tool tip in the direction of the tool tip, as well as the use of the bonding arrangement or the bonding tool for laser-supported ultrasonic bonding.

### Description of the Background Art

A bonding tool is known from the post-published German patent application 10 2017 129 546 of the applicant, which includes a blind hole-like longitudinal recess, which extends from an end face of the bonding tool, along a tool shank thereof, to a tool tip. The blind hole-like longitudinal recess is designed as completely closed on the lateral surface. It is used to conduct a laser beam in the interior of the bonding tool, which is used to heat the tool tip during bonding. For example, a light guide may be provided in the longitudinal recess for conducting the laser beam

In practice, it has been demonstrated that, during the operation of a conventional laser, a contamination may occur in the area of the longitudinal recess itself or of the light guide provided in the longitudinal recess, in particular in the area of a conventional tool tip. The efficiency decreases hereby, and the tool tip is heated more slowly. In addition, the light guide may become damaged or destroyed.

### SUMMARY OF THE INVENTION

It is therefore an object of the present invention to provide an improved bonding arrangement and an improved bonding tool, in which the contamination is prevented or counteracted.

In an exemplary embodiment, a functional recess is formed on the lateral surface of the bonding tool, the longitudinal recess being made to extend up to the functional recess or opening thereinto.

The particular advantage of the invention is that, during the heating of the tool tip with the aid of the laser beam, particles detached from the bonding tool may exit through the functional recess, thereby counteracting a contamination of the light guide. Moreover, a free end of the light guide facing the tool tip may be inspected via the functional recess and cleaned if necessary, or particles adhering to the free end of the light guide may be removed. In each case, this increases the lifetime of the tool or the efficiency during the heating of the tool tip.

In addition, the heat flow from the tool tip in the direction of the tool shank is reduced by the provision of the functional recess. The heat flow is in proportion to a cross-sectional surface of the bonding tool, and, due to the functional recess, the cross-sectional surface is smaller compared to an otherwise geometrically identical bonding tool without a functional recess. In this regard, the heating of the tool tip is improved and accelerated, since less heat enters the tool shank, and the efficiency is increased.

The functional recess is provided on a lateral surface of the tool, which connects the end face of the bonding tool to an underside of the bonding tool. The underside of the bonding tool is situated opposite the end face of the bonding tool. A bonding contact surface is provided on the underside, which is used and designed to be applied to a first connecting partner during the establishment of the bond connection and to press the first connecting partner against a second connecting partner. For example, a V-shaped guide groove extending transversely to the tool longitudinal direction is provided for a bonding wire (connecting partner) on the underside of the bonding tool.

The tool lateral surface of the bonding tool extends in the area of the tool shank and the tool tip. A transition from the tool shank of the bonding tool to the tool tip is defined, for example, by a change in the outer geometry of the bonding tool. In a bonding tool for ultrasonic wire bonding, the bonding tool tapers in the area of the tool tip in the direction of the underside of the bonding too, for example in a wedge-shaped manner.

For example, a glass fiber or a glass fiber bundle may be provided as the light guide for the laser beam. For example, a plastic or glass rod may be provided as the light guide. For example, a tube may be used as the light guide for conducting the laser beam.

The functional recess can be designed in the manner of a radiation trap in such a way that at least one boundary surface of the functional recess is designed as a deflecting surface and/or absorption surface for the laser. The deflecting surface of the functional recess is arranged, on the one hand, in such a way that a laser beam conducted in the light guide strikes the deflecting surface after it emerges from the light guide and is then deflected thereon in such a way that a reflection in the direction of the light guide is avoided. The deflecting surface of the functional recess thus has a positioning angle of 0° or 90° with respect to the tool longitudinal direction or is provided with a curved design. For example, the functional recess may taper in a wedge-shaped manner in the direction of the tool tip for implementing the radiation trap function. The provision of the deflecting surface advantageously prevents the laser beam from being reflected in the direction of the light guide and causing damage thereto. Finally, by providing the limiting surface, the surface heated by the laser beam is enlarged, with the result that the tool tip is heated more homogeneously, or a damage to the tool by an impermissibly high local heating is counteracted. Due to the enlargement of the heated surface, the intensity is likewise reduced and consequently also the number of particles detached during the heating of the tool tip, which are thrown back in the direction of the light guide.

The functional recess can be at least partially and preferably completely formed on the tool tip. This arrangement advantageously favors the local heating of the tool tip, or an undesirable heating of the tool shank is counteracted. The process times may be reduced due to the local heating of the tool tip.

According to an example of the invention, a width of the functional recess determined transversely to the tool longitudinal direction, on the one hand, and a depth of the functional recess determined transversely to the tool longitudinal direction and orthogonally to the width of the functional recess are dimensioned in such a way that a diagnostic tool is insertable into the functional recess for the purpose of testing the function of the light guide. The functionality or the performance of the light guide may be advantageously determined by the function test. In this regard, it is possible to detect impermissible contamination states early on and/or determine an optimal maintenance time at which the bonding tool and/or the light guide is/are replaced or cleaned.

For example, a rod mirror, which is designed to deflect the laser beam by, for example, 90° or operates in a periscopic manner and permits an optical inspection of the light guide, is inserted into the functional recess as the diagnostic tool. For example, the contamination degree of the light guide may be determined with the aid of a power measuring device.

The functional recess may be manufactured, for example, by means of wire-cut EDM and/or die-sink EDM. In this regard, the functional recess is formed at a later time on a lateral surface of an existing bonding tool. For example, the functional recess may be formed directly during the manufacturing of the bonding tool. The bonding tool, including the functional recess and the longitudinal recess, may thus be manufactured, for example, by primary shaping.

The laser beam may be fully reflected on the lateral surface of the light guide. To implement the full reflection, the light guide may optionally provide a reflective coating on the lateral surface, at least in sections. The laser beam may be particularly effectively conducted in the light guide hereby. The reflective coating may be designed, for example, in such a way that, in particular radiation having the special wavelength used by the laser employed for providing the laser beam is reflected by the light guide and is conducted by the light guide with little loss.

The longitudinal recess of the bonding arrangement according to the invention may extend in the longitudinal direction of the tool. Likewise, it may be provided that the light guide extends in the longitudinal recess in the longitudinal direction of the tool. The light guide and the longitudinal recess may have, for example, a constant, circular cross-section and/or be arranged coaxially to each other. The light guide may be provided in the longitudinal recess, for example with the aid of a clearance fit.

A width of the functional recess should always be smaller than two-thirds of a corresponding outer width of the bonding tool. The width of the functional recess and the corresponding width of the bonding tool are measured at an identical location of the bonding tool. An always sufficient mechanical stability of the bonding tool may be advantageously ensured by limiting the width of the functional recess. At the same time, it may be ensured that the ultrasonic vibrations are effectively transmitted, in particular during ultrasonic bonding, or a reproducible bending and/or longitudinal vibration forms in the bonding tool.

The functional recess can be designed as a through-recess. In this regard, the functional recess provides two openings on the lateral surface, which are preferably situated opposite each other. Designing the functional recess as a through-recess advantageously makes the manufacturing of the functional recess particularly easy. At the same time, the functional recess designed as a through-recess may be used to conduct compressed air or provide an air flow, so that, if necessary, the tool tip is cooled and, in particular, the particles which have become detached during the heating of the tool tip are conducted laterally out of the bonding tool. Moreover, the formation of a through-recess is advantageous, in particular, using wire-cut EDM.

The functional recess may be formed in the shape of a pocket. The stability of the bonding tool may be increased hereby. In addition, the encapsulation of the laser beam or a scattering of the laser beam is improved and a striking of the laser beam on surfaces outside the bonding tool is better counteracted by the trough shape, since the laser beams are unable to exit, due to the closed side of the trough. For example, the pocket-shaped or trough-shaped recess may be manufactured by means of die-sink EDM.

The free end of the light guide facing the tool tip may be conducted through the longitudinal recess of the bonding tool into the functional recess. The correct mounting and positioning of the light guide may be advantageously controlled in a particularly easy manner. At the same time, the optical inspection of the light guide is made easier during the determination of the degree of contamination and the cleaning of the light guide.

The free end of the light guide assigned to the tool tip may be provided in the longitudinal recess. The arrangement of the light guide is advantageously particularly protected in this case, and a contamination of the light guide by detached particles is prevented.

Within the meaning of the invention, the free end of the light guide can be arranged in the longitudinal recess if the free end of the light guide is arranged in the longitudinal recess at a distance from the functional recess. Within the meaning of the invention, the free end of the light guide is likewise arranged in the longitudinal recess if the free end of the light guide or an end face of the light guide formed on the free end, which serves as the outlet surface for the laser beam, is situated exactly in the transition between the longitudinal recess and the functional recess.

Further, a functional recess can be formed on the lateral surface of the bonding tool, the longitudinal recess being made to extend up to the functional recess.

The bonding tool can be provided with a symmetrical design with respect to a longitudinal center plane. Particularly advantages vibration characteristics for the bonding tool result hereby, so that the symmetrical bonding tool is suitable, in particular, for ultrasonic bonding and specifically for use in ultrasonic wire bonding.

Additional advantages, features and details of the invention are apparent from the additional subclaims and the following description. Features mentioned therein may each be essential to the invention both individually or in any arbitrary combination. Features and details of the bonding arrangement described according to the invention naturally also apply in connection with the bonding tool according to the invention and vice versa. Thus, reference may always be made interchangeably to the disclosure of the individual aspects of the invention. The drawings are used only to clarify the invention based on examples and are not limiting in nature.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a front side view of a bonding tool according to the invention, including a longitudinal recess and a functional recess arranged orthogonally thereto, which is designed as a through-recess in the area of a tool tip of the bonding tool;

FIG. 2 shows a detail X of the bonding tool according to FIG. 1 in an enlarged representation;

FIG. 3 shows an longitudinal side view of the bonding tool according to FIG. 1;

FIG. 4 shows a underside view of the bonding tool according to FIG. 1;

FIG. 5 shows a first alternative specific embodiment of a bonding arrangement according to the invention in a front side view;

FIG. 6 shows the bonding arrangement according to FIG. 5 in a longitudinal side view;

FIG. 7 shows the bonding arrangement according to FIG. 5 in an underside view;

FIG. 8 shows a second alternative specific embodiment of a bonding arrangement according to the invention in a front side view;

FIG. 9 shows a third alternative specific embodiment of a bonding arrangement according to the invention in a front side view;

FIG. 10 shows a fourth alternative specific embodiment of a bonding arrangement according to the invention in a front side view;

FIG. 11 shows a fifth alternative specific embodiment of a bonding arrangement according to the invention in a front side view; and

FIG. 12 shows a sixth alternative specific embodiment of a bonding arrangement according to the invention in a front side view.

### DETAILED DESCRIPTION

The figures show different exemplary embodiments of the bonding arrangement according to the invention. The same elements, or those having the same functions, are marked by the same reference numerals. Only the features which differ from those of the first exemplary embodiment are explained for the exemplary embodiments following the first exemplary embodiment. The exemplary embodiments otherwise correspond to each other.

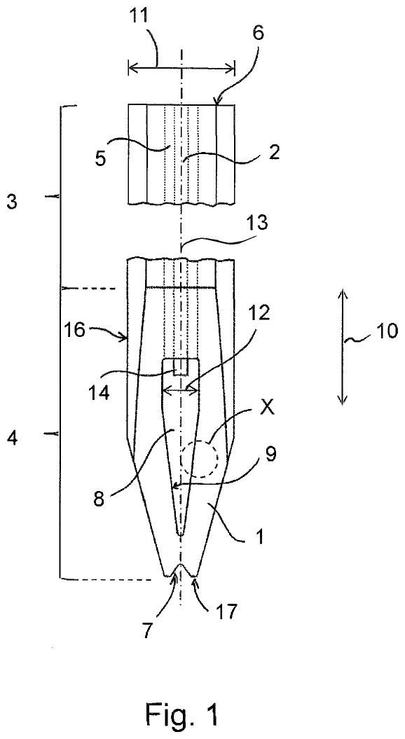

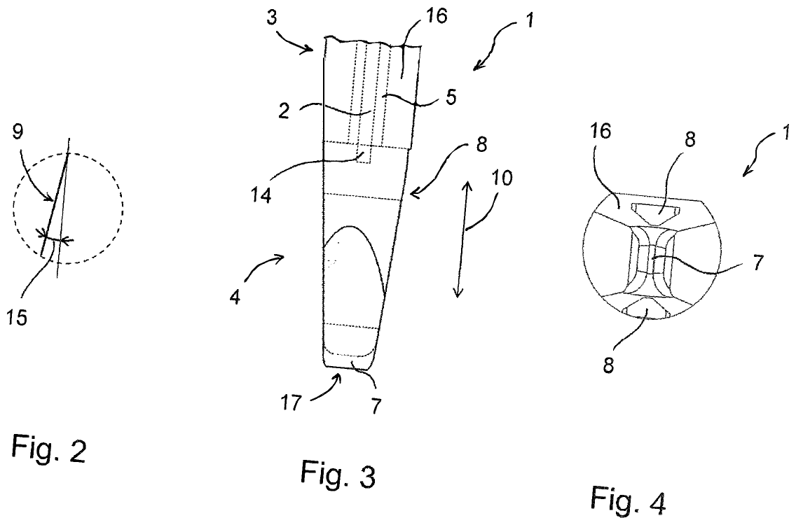

According to FIGS. 1 through 4, a bonding arrangement according to the invention comprises a bonding tool 1 and a light guide 2, which is conducted in a longitudinal recess 5 of bonding tool 1 and is implemented, for example, as a glass fiber or plastic rod. Bonding tool 1 provides a tool shank 3, which is designed as elongated in a tool longitudinal direction 10. Bonding tool 1 further provides a tool tip 4, which adjoins tool shank 3. Longitudinal recess 5 of the bonding tool extends in tool longitudinal direction 10 from an end face 6 of bonding tool 1 opposite tool tip 4 in the direction of tool tip 4. At tool tip 4, end face 6 is provided with an oppositely situated underside 17, including a guide groove extending transversely to tool longitudinal direction 10. The guide groove is designed to receive a bonding wire, which is not illustrated. In the area of the guide groove, bonding tool 1 adjoins the bonding wire on the lateral side with a bonding contact surface 7 during the establishment of the bond connection.

Moreover, a functional recess 8 is formed on tool tip 4. Functional recess 8 is formed on a tool lateral surface 16 of bonding tool 1, which connects end face 6 to underside 17. Functional recess 8 is designed as a through-recess. It is oriented orthogonally to tool longitudinal direction 10.

Longitudinal recess 5 of bonding tool 1 extends up to functional recess 8 and opens thereinto. Light guide 2 conducted in longitudinal recess 5 projects into functional recess 8 with a free end 14 facing tool tip 4.

In an area adjacent to longitudinal recess 5, functional recess 8 provides a constant width 12 and then tapers in a wedge-shaped manner in the direction of underside 17 of tool tip 4. In the area of the wedge-shaped tapering, two oppositely situated boundary surfaces 9 of functional recess 8 are designed as absorption or deflecting surfaces for the laser beam, which is guided in light guide 2. Deflecting surfaces 9 are provided with a flat design and are arranged in an inclined manner at an acute positioning angle 15 with respect to tool longitudinal direction 10.

In the present exemplary embodiment of the invention, width 12 of functional recess 8 defined orthogonally to tool longitudinal direction 10 is smaller in each case than two-thirds of a corresponding outer width 11 of bonding tool 1. Bonding tool 1 is thus always provided with a sufficient amount of material to ensure an adequate mechanical stability even in the area of functional recess 8.

Bonding tool 1 is provided with a symmetrical design with respect to a longitudinal center plane 13 thereof. The symmetry favors the vibration characteristics of bonding tool 1.

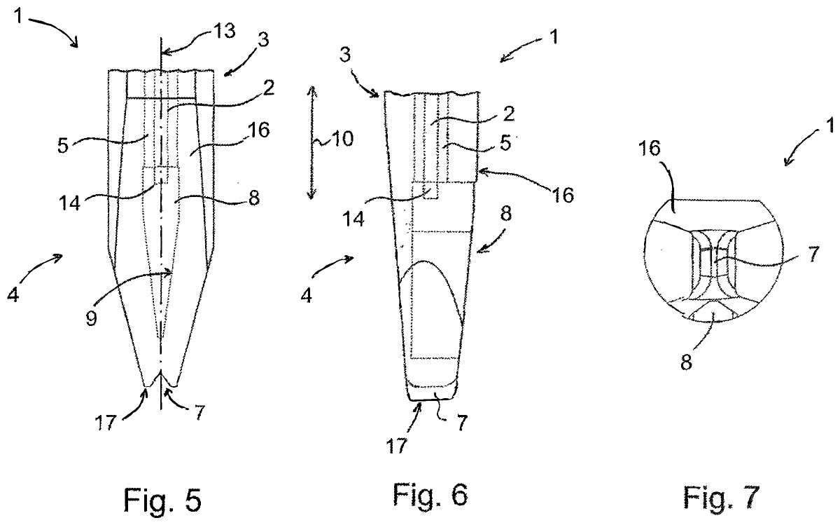

A first alternative specific embodiment of the bonding arrangement according to the invention is illustrated in FIGS. 5 through 7. The bonding tool provides a functional recess 8 of the same shape but now designed in a pocket-like or trough-like manner, viewed from above. Functional recess 8 is thus not designed as a through-recess. It is limited by a wall 18 on the front side. Otherwise, the bonding arrangement corresponds to the one discussed above. In particular, the depth of the functional recess is further defined in such a way that longitudinal recess 5 opens into functional recess 8.

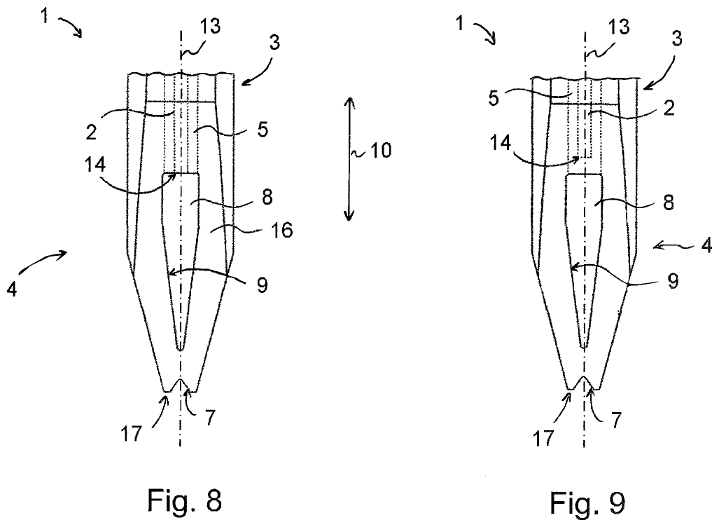

According to FIG. 8, a second alternative specific embodiment of the bonding arrangement according to the invention provides that light guide 2 is arranged in longitudinal recess 5 of bonding tool 1 in such a way that an outlet surface facing underside 17 is arranged exactly where longitudinal recess 5 ends or opens into functional recess 8. Free end 14 of light guide 2 thus does not project into functional recess 8.

According to FIG. 9, according to a third alternative specific embodiment of the bonding arrangement according to the invention, it is provided that free end 14 of light guide 2 is withdrawn and arranged in longitudinal recess 5 at a distance from functional recess 8.

In each case, an improved protection against contamination of light guide 2 results due to the arrangement of free end 14 of light guide 2 in longitudinal recess 5. In addition, light guide 2 is provided in longitudinal recess 5, protected against mechanical influences and damage.

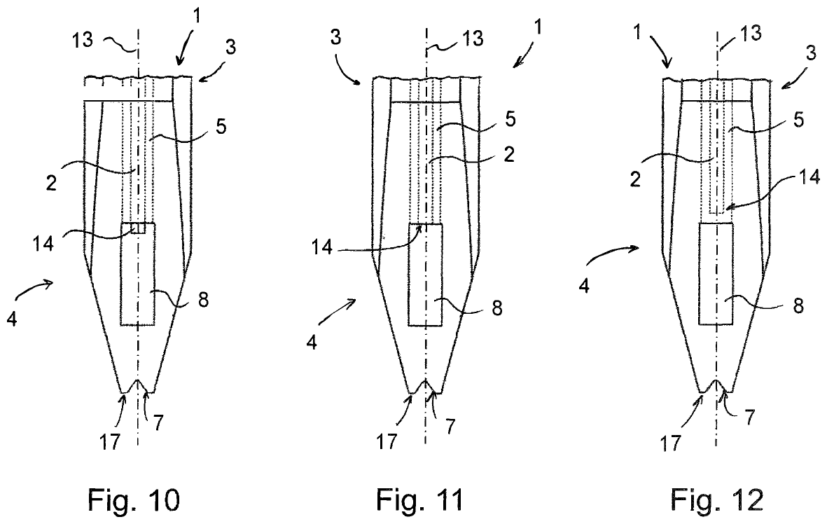

While functional recess 8 according to the first three exemplary embodiments of the invention tapers in a wedge-shaped manner in the direction of underside 17 of tool tip 4, the further exemplary embodiments four, five and six of the invention in FIGS. 10 through 12 provide a rectangular functional recess 8 in cross-section. As before, functional recess 8 is arranged completely in the area of tool tip 4 and is implemented in each case as a through-recess. Of course, it may be alternatively provided that functional recess 8 is provided with a pocket-shaped design.

As discussed above, light guides 2 may either extend into functional recess 8 (FIG. 10) or—as shown in FIGS. 11 and 12—the outlet surface for the laser beam may be arranged in alignment with an opening of longitudinal recess 5 assigned to functional recess 8, or free end 14 of light guide 2 may be provided in a withdrawn manner in longitudinal recess 5.

According to an alternative specific embodiment of the invention, which is not illustrated, width 12 of functional recess 8 may increase in size, at least in sections, in the direction of underside 17. For example, functional recess 8 may be provided with a conical or frustoconical design. For example, width 12 of functional recess 8 may be defined in such a way that the laser beam does not strike the lateral limiting surfaces of functional recess 8 but rather a lower boundary surface of functional recess 8 assigned to underside 17 of bonding tool 1 and situated opposite free end 14 of light guide 2. An outflow of thermal energy in the direction of the tool shank and/or a clamping point of bonding tool 1 may then be reduced.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A bonding arrangement comprising:
a bonding tool having a tool shank, which is designed as elongated in a tool longitudinal direction and having a tool tip, which adjoins the tool shank;
a light guide designed to conduct a laser beam, the light guide being provided in a longitudinal recess of the bonding tool, the longitudinal recess extending from an end face of the bonding tool opposite the tool tip in a direction of the tool tip; and
a functional recess formed on a lateral surface of the bonding tool, the longitudinal recess extending towards the functional recess.

2. The bonding arrangement according to claim 1, wherein the functional recess is a radiation trap such that at least one boundary surface of the functional recess is designed as a deflecting surface for the laser beam; and wherein the functional recess has a positioning angle deviating by 0° and by 90° with respect to the tool longitudinal direction and/or is provided with a curved design.

3. The bonding arrangement according to claim 1, wherein the longitudinal recess is made to extend up to the tool tip, and/or the functional recess is at least partially formed on the tool tip.

4. The bonding arrangement according to claim 1, wherein a width of the functional recess defined transversely to the tool longitudinal direction and a depth of the functional recess defined transversely to the tool longitudinal direction as well as orthogonally to the width of the functional recess are dimensioned such that a diagnostic tool is insertable into the functional recess to test a function of the light guide.

5. The bonding arrangement according to claim 1, wherein a bonding contact surface is formed on the tool tip, and wherein the functional recess tapers in a direction of the bonding contact surface, and/or wherein the bonding contact surface is provided with a closed flat design.

6. The bonding arrangement according to claim 1, wherein the functional recess is manufactured by wire-cut EDM and/or by die-sink EDM or by additive manufacturing methods and/or by primary forming.

7. The bonding arrangement according to claim 1, wherein the light guide includes a glass fiber or a glass fiber bundle, and/or the light guide is coated from the outside with a reflective coating, at least in sections.

8. The bonding arrangement according to claim 1, wherein the width of the functional recess is smaller than two-thirds of a corresponding width of the bonding tool.

9. The bonding arrangement according to claim 1, wherein a cross-section of the functional recess is larger than a cross-section of the longitudinal recess at least in sections or adjacent to the longitudinal recess, and/or wherein the cross-section of the functional recess is constant, at least in sections.

10. T The bonding arrangement according to claim 1, wherein the functional recess is provided with a pocket-shaped design.

11. The bonding arrangement according to claim 1, wherein the functional recess is designed as a through-recess.

12. The bonding arrangement according to claim 1, wherein the light guide is inserted into the functional recess.

13. The bonding arrangement according to claim 1, wherein a free end of the light guide assigned to the tool tip is provided in the longitudinal recess.

14. A bonding tool comprising:
a bonding arrangement according to claim 1;
a tool shank elongated in a tool longitudinal direction;
a tool tip, which adjoins the tool shank;
a longitudinal recess, which extends from an end face of the bonding tool opposite the tool tip in the direction of the tool tip; and
a functional recess formed on the lateral surface of the bonding tool, the longitudinal recess being made to extend up to the functional recess.

15. The of a bonding arrangement according to claim 1, wherein the bonding arrangement is adapted for laser-supported ultrasonic bonding and/or for laser-supported ultrasonic wire bonding.
